(19) United States
(12) Patent Application Publication
(10) Pub. No.: US 2013/0154091 A1
(43) Pub. Date: Jun. 20, 2013

(54) SEMICONDUCTOR DEVICE PACKAGING USING ENCAPSULATED CONDUCTIVE BALLS FOR PACKAGE-ON-PACKAGE BACK SIDE COUPLING

(71) Applicants: Jason R. Wright, Chandler, AZ (US); Zhiwei Gong, Chandler, AZ (US); Scott M. Hayes, Chandler, AZ (US); Douglas G. Mitchell, Tempe, AZ (US)

(72) Inventors: Jason R. Wright, Chandler, AZ (US); Zhiwei Gong, Chandler, AZ (US); Scott M. Hayes, Chandler, AZ (US); Douglas G. Mitchell, Tempe, AZ (US)

(21) Appl. No.: 13/325,092

(22) Filed: Dec. 14, 2011

(51) Int. Cl. H01L 23/498; H01L 21/50

(52) U.S. Cl. 257/738; 438/118; 438/107; 438/127; 257/E21.499; 257/E23.069

(57) ABSTRACT

A semiconductor device package having an embedded three-dimensional interconnect structure and a process for making such a package is provided. One or more ball conductors are attached to a major surface of a substrate that provides at least an electrical conduit from the ball conductor to an opposite major surface of the substrate. The substrate can also provide an interconnect between solder balls. The combination of solder balls and substrate is encapsulated in the semiconductor device package. The ends of the signal conduits are exposed on one major surface of the device package, while a portion of the ball conductors is exposed on the opposite major surface of the device package. The ball conductors and signal conduits provide signal-bearing pathways between the major surfaces of the package. Contacts created by the back grinded ball conductors are used to form a package-on-package structure by coupling with contacts from another package.

### BACKGROUND

1. Field

This disclosure relates generally to semiconductor device packaging, and more specifically, to providing through-package vias and back side coupling in an encapsulated device package by using pre-formed signal conduits and conductive balls.

2. Related Art

Semiconductor and other types of electronic devices are often encapsulated wholly or partly in resin to provide environmental protection and facilitate external connection to the devices. Subsequent to encapsulation, interconnect structures can be built up on one or both sides of the encapsulated devices to allow for package-on-package arrangements. For packages having electrical contacts on both top and bottom surfaces (e.g., a double-sided buildup), through-vias are often made to provide contacts between bottom side and top side interconnect structures. Traditionally, through package vias are made after encapsulation using a drilling and filling/metallization process that includes steps for via drill, via fill/metallization, polish and taping, and so on. Further, the formation of buildup layers on both sides of the package to create coupling pads involves many additional steps. This process of post-encapsulation via and interconnect formation introduces complexities to the manufacturing process that have a variety of manufacturing and reliability challenges. Further, costs associated with materials, processes and additional tooling to generate the through vias and interconnects can be high. In addition, through mold vias with double sided buildup allow for more complex system-in-package designs which may not be needed for simple package-on-package arrangements.

It is therefore desired to have a process for creating electrical couplings on a top side of a semiconductor package without adding significant cost or process steps. It is further desired that the through via creation process be simplified or eliminated along with many of the panelization steps relating to double-sided interconnect buildup. In addition, providing contacts on a top side of a semiconductor package without a complex buildup process will also allow for a thinner package for the device and, ultimately, a thinner package-on-package stack.

### BRIEF DESCRIPTION OF THE DRAWINGS

The present invention may be better understood, and its numerous objects, features, and advantages made apparent to those skilled in the art by referencing the accompanying drawings.

FIG. 1 is a simplified block diagram illustrating a cross-sectional view of a device structure after die and signal conduits are placed on an adhesive layer and carrier, according to an embodiment of the present invention.

FIG. 2 is a simplified block diagram illustrating the cross sectional view of the device structure of FIG. 1 after encapsulation of placed components in the processing example.

FIG. 3 is a simplified block diagram illustrating the cross sectional view of the device structure of FIG. 2 after reducing the thickness of encapsulant in the processing example.

FIG. 4 is a simplified block diagram illustrating the cross sectional view of the device structure of FIG. 3 after releasing the encapsulated components from the carrier and adhesive layer in the processing example.

FIG. 5 is a simplified block diagram illustrating the cross sectional view of the device structure of FIG. 4 after bottom side buildup, ball placement and singulation.

FIG. 6 is a simplified block diagram illustrating an example of a cross sectional view of the device structure after buildup, ball placement and singulation electrically coupled to another device structure using the top side conductive surfaces.

FIG. 7 shows a cross section of the device structure coupled to a different device structure after buildup, ball placement and singulation, using the top-conductive surfaces.

FIG. 8 is a simplified block diagram illustrating a perspective view of an example of a substrate with coupled ball conductors, according to one embodiment of the present invention.

FIG. 9 is a simplified block diagram illustrating a perspective view of a packaged device having connections exposed on both sides, in accord with embodiments of the present invention.

The use of the same reference symbols in different drawings indicates identical items unless otherwise noted. The figures are not necessarily drawn to scale.

### DETAILED DESCRIPTION

A semiconductor device package having an embedded three-dimensional interconnect structure and a process for making such a package is provided. One or more ball conductors or similar structures (e.g., gold studs) are attached to a major surface of a substrate that provides at least an electrical conduit (e.g., conductive pillars) from the ball conductor to an opposite major surface of the substrate. In addition, the substrate can provide a two-dimensional interconnect between ball conductors. The combination of ball conductors and substrate is subsequently embedded in an encapsulated semiconductor device package. The ends of the signal conduits are exposed on one major surface of the device package, while the opposite major surface of the device package is back grinded (or the equivalent) to expose a portion of the ball conductors. The conductive pathway of ball conductors and signal conduits are then used as through vias, providing signal-bearing pathways between the bottom and top major surfaces of the package. The “pads” created by the back grinded ball conductors can be used to form a package-on-package structure by being coupled with contacts from another package. The ball conductor/substrate combination can be provided in a variety of geometries and materials, depending upon the nature of the application.

For convenience of explanation, and not intended to be limiting, the present invention is described for semiconductor devices, but persons of skill in the art will understand that the present invention applies to any type of electronic device that is substantially planar. Accordingly, such other types of devices including the non-limiting examples given below, are intended to be included in the terms “device,” “semiconductor device,” and “integrated circuit” whether singular or plural, and the terms “device,” “die,” and “chip” are intended to be substantially equivalent. Non-limiting examples of suitable devices are semiconductor integrated circuits, individual semiconductor devices, piezoelectric devices, solid-state filters, magnetic tunneling structures, integrated passive devices such as capacitors, resistors and inductors, and combinations and a raise of any and all of these types of devices and elements. Further, embodiments of the present invention do not depend upon the types of die or chips being used nor the materials of which they are constructed provided that such materials withstand the encapsulation process.

The following detailed description is merely exemplary in nature and is not intended to limit the invention or the application and uses of the invention. Furthermore, there is no intention to be bound by any expressed or implied theory presented in the preceding technical field, background, brief summary or the following detailed description. In some examples, the signal conduit for passing a signal from one side of the device package to another is described as a conductive via or pillar. It should be recognized that such examples are not intended to limit embodiments of the present invention to electrically conductive materials, as the signal conduit can include additional materials such as waveguide for passing optical signals.

FIG. 1 is a simplified block diagram illustrating a cross-sectional view of a device structure 100 at a stage in one example of processing, according to an embodiment of the present invention. A substrate 110 having an interconnect that includes signal conduits 120 and an interconnect layer 130 (or routing layer) is electrically coupled to one or more ball connectors 140. In one embodiment, ball connectors 140 are solder balls. As will be discussed in greater detail below, ball connectors 140 should be of a material that can withstand a grinding or polishing process and provide a solderable finish after the grinding or polishing process. Substrate 110 is placed on an adhesive layer 150 on a carrier 160. Adhesive layer 150 can be of a standard type used in semiconductor packaging processing including, for example, a double-sided polyimide sticky tape having a silicone adhesive on both sides. The adhesive layer should be of a type that can withstand the packaging processing without becoming brittle or permanently fixed in place, since at a later point in processing the adhesive layer will be separated from the package. In addition to the substrate/ball connector assemblies, at least one die 170 is placed active surface face down on adhesive layer 150. In alternative embodiments, the die need not be placed for applications using only a discrete, solderable through via structure (e.g., an interposer). The “active surface” of die 170 is a surface of the die having bond pads 180 and 185.

Signal conduits 120 can be made from a variety of electrically conductive materials including, for example, copper, gold, silver, aluminum, tungsten, and alloys thereof to include solder, doped materials (e.g., phosphorus, boron-doped polysilicon), superconducting materials and ceramics (e.g., copper oxide materials (such as HgBa₂Ca₂Cu₃Oₓ, and Bi₂Sr₂Ca₂Cu₃O₁₀ (BSCCO)), iron-based materials (such as SmFeAs(O,F)) and other metallic-based materials (such as Nb₃Sn)), the choice of which is dependent upon the nature of the application. Signal conduits 120 could also be made of more than one type of material depending on the process to create the conduits, assembly and particular package structures.

Substrate 110 can be provided in a variety of shapes, depending upon the nature of the application and the package layout (e.g., strips and squares). Signal conduits 120 can be attached to the substrate through a molding process, pressing, deposition, or other methodologies appropriate to the nature of the materials of both the conduits and the substrate.

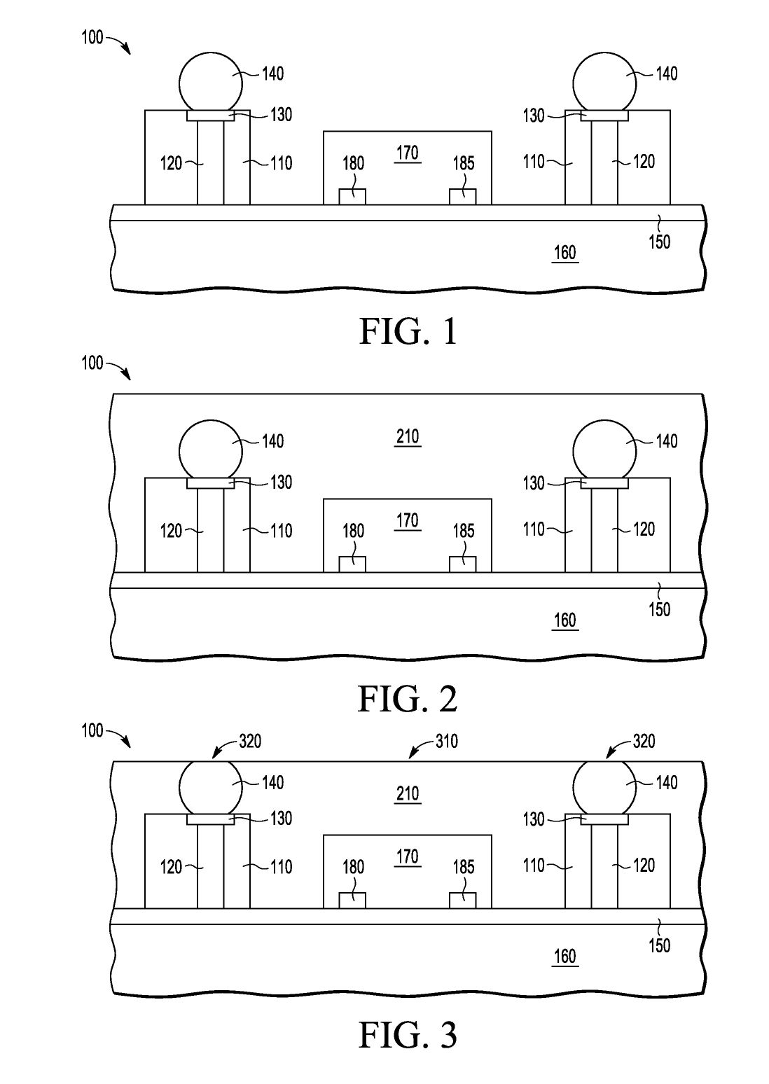

FIG. 2 is a simplified block diagram illustrating the cross sectional view of device structure 100 at a later stage in the processing example. A molding material is applied to the structures affixed to adhesive layer 150 (e.g., substrate 110, ball connectors 140, and die 170), forming an encapsulant 210 that encapsulates the structures within the molding material and forms a panel. The molding material can be any appropriate encapsulant including, for example, silica-filled epoxy molding compounds, plastic encapsulation resins, and other polymeric materials such as silicones, polyimides, phenolics, and polyurethanes. The molding material can be applied by a variety of standard processing techniques used in encapsulation including, for example, printing, compression molding and spin application. Once the molding material is applied, the panel can be cured by exposing the materials to certain temperatures for a period of time, or by applying curing agents, or both. In a typical encapsulation process, a depth of encapsulant 210 can exceed a maximum height of structures embedded in the molding material (e.g., the height of ball connectors 140 as illustrated in FIG. 2).

FIG. 3 is a simplified block diagram illustrating the cross sectional view of device structure 100 at a later stage in the processing example. Encapsulant 210 is reduced in thickness to expose a portion of ball connectors 140. This reduction in thickness of the encapsulant and exposing of the ends of the signal conduits can be performed by conventional techniques, such as, for example, a grinding, lapping or polishing process. The reduction in thickness process exposes a surface 310 of the encapsulant, as well as conductive surfaces 320 of ball connectors 140. As will be appreciated, as the reduction in thickness process is performed down to the middle of the ball connectors, the area of conductive surfaces 320 increases. Thus, the depth of the reduction in thickness process (e.g., grinding) can be determined by the nature of the connectors that will be in contact with conductive surfaces 320 in a stacked package-on-package configuration.

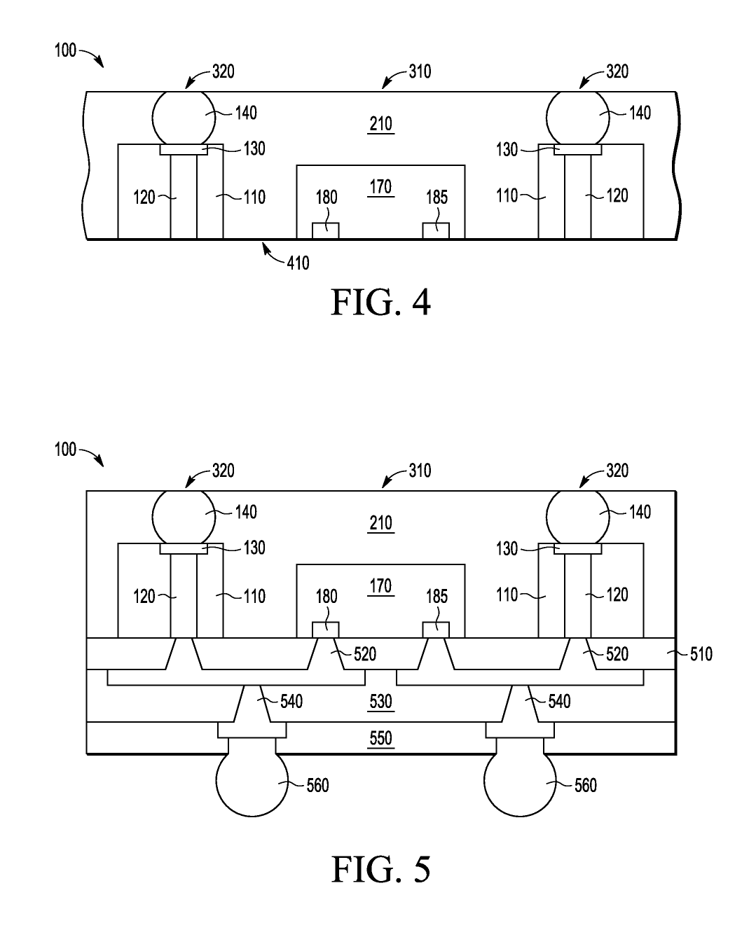

FIG. 4 is a simplified block diagram illustrating the cross sectional view of device structure 100 at a later stage in the processing example. The encapsulated panel is removed from adhesive layer 150 (and carrier 160). Once released from the tape, the side of the panel previously attached to the tape can be cleaned to remove any excess adhesive remaining attached to the encapsulated panel. This process of tape release and clean exposes all of the contacts on the bottom side of the panel, including the bottom ends of signal conduits 120 and bond pads 180 and 185. At this point, it can be seen that signal conduits 120, in association with ball connectors 140, form conductive pathways, or through vias, between the top and bottom surfaces of the encapsulated panel. These conductive pathways can be used, for example, to enable electrical connection between interconnect structures or pads formed on the bottom of a package formed from the panel and top connectors formed from conductive surfaces 320.

FIG. 5 is a simplified block diagram illustrating the cross sectional view of device structure 100 after bottom side buildup, ball placement and singulation. Processing providing the various layers illustrated in FIG. 5 can be provided by standard techniques and materials used in semiconductor packaging.

An insulating layer 510 can be deposited over the bottom surface of the encapsulated die, signal conduits and encapsulation molding material. Insulating layer 510 can be made from organic polymers, for example, in liquid or dry film and can include a wide range of other materials used for interlayer dielectrics as known in the art (e.g., silicon dioxide, silicon nitride, silicon oxynitride, or any combination of such layers providing electrical isolation). Insulating layer 510 can be patterned to expose bonding pads 180 and 185, as well as the ends of signal conduits 120.

A conductive layer 520 can then be deposited to provide an interconnect between the bonding pads and signal conduits. Conductive layer 520 can include materials such as metal, metal alloy, doped semiconductor, semi-metals, or combinations thereof as known in the art (e.g., amorphous silicon, doped polysilicon, aluminum, copper, silver, gold, tantalum, titanium, tungsten, or any metal alloy, nitride or silicide). Through the use of a conductive layer, any number of bonding pads can be interconnected in any combination to the same or other die and to the vias formed in insulating layer 510 by electrically conductive signal conduits. The interconnect illustrated in FIG. 5 is provided only by way of example, and it should be realized that the interconnects formed by conductive layer 520 and other conductive layers discussed below can extend not only across the page as illustrated but also into and above the page.

An additional interconnect layer can be provided by forming additional insulating layers (e.g., insulating layer 530) and patterning those insulating layers with vias to receive additional conductive layers (e.g., conductive layer 540). The range of materials that can be used for subsequent insulating layers and conductive layers can include those listed for insulating layer 510 and conductive layer 520, and each type of layer can be the same or different materials as required by the nature of the application. Further, as illustrated, a set of conductive ball connectors can be provided by forming insulating layer 550, patterning that layer to expose pads formed in conductive layer 540, and forming and placing conductive balls 560 using standard techniques and materials.

FIG. 5 illustrates a double-sided semiconductor package, in which conductive areas are provided on the top side of the package. The conductive pathways formed by electrically conductive signal conduits 120 and ball connectors 140 allow for connections to be made between the bottom side interconnect and the top side conductive surfaces 320. An advantage of forming conductive surfaces in accord with embodiments of the present invention is that additional processing steps are not needed for forming a top side interconnect. The combination of ball connectors 140, signal conduits 120 and interconnect 130 provide an interconnect usable for package-on-package configurations. Other package components can be directly attached to the top-side conductive surfaces formed from the ball connectors.

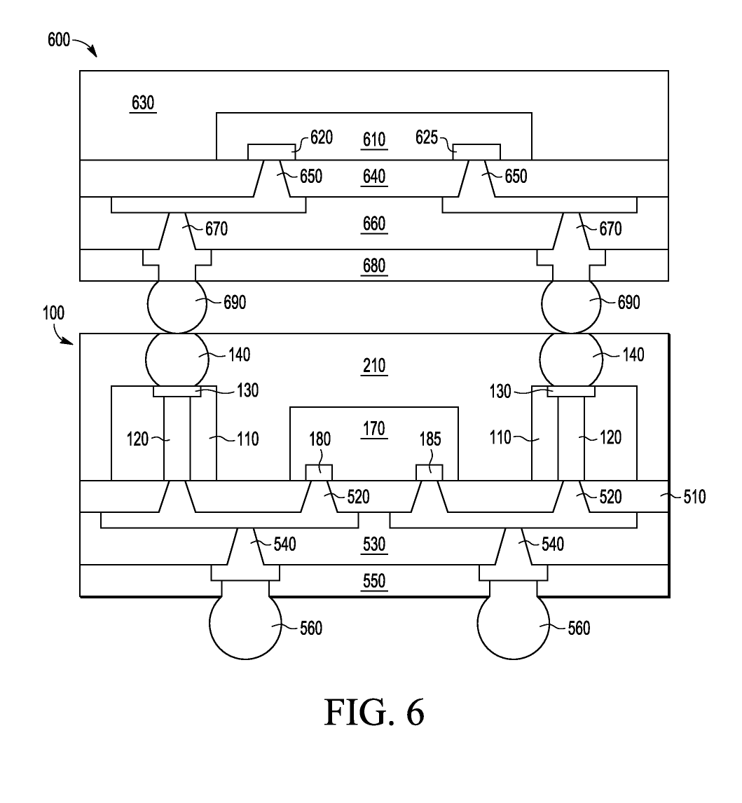

FIG. 6 is a simplified block diagram illustrating an example of a cross sectional view of device structure 100 after buildup, ball placement and singulation electrically coupled to a device structure 600 using the top-conductive surfaces. Device structure 600 includes a die 610 with bond pads 620 and 625. Die 610 is encapsulated in a encapsulant 630. An interconnect is formed on the bottom side of device structure 600. An insulating layer 640 is formed over the bottom surface of encapsulated die 610 and encapsulation molding material. Insulating layer 640 can be patterned to expose bond pads 620 and 625. A conductive layer 650 is formed to provide an interconnect from the bond pads. Again, this interconnect illustrated in FIG. 6 is provided only by way of example, and it should be realized that the interconnect formed by conductive layer 650 and other conductive layers discussed below can extend not only across the page as illustrated but also into and above the page.

An additional interconnect layer can be provided by forming additional insulating layers (e.g., insulating layer 660) and patterning those insulating layers to receive additional conductive layers (e.g., conductive layer 670). Further, as illustrated, a set of conductive ball connectors can be provided by forming insulating layer 680, patterning that layer to expose pads formed in conductive layer 670, and forming and placing conductive balls 690 using standard techniques and materials. The range of materials that can be used for the insulating layers and conductive layers of device 600 can include those listed for insulating layer 510 and conductive layer 520 of device 100, and each type of layer can be the same or different materials as required by the nature of the application.

Conductive balls 690 are in a configuration that matches one or more of the conductive surfaces (320) of device 100 formed from the grinded ball conductors 140. The conductive balls and the conductive surfaces can be affixed to one another using typical means (e.g., solder reflow and the like). An advantage of using a solder ball for a ball conductor 140 is that the solder ball will provide a solderable finish after the grinding step.

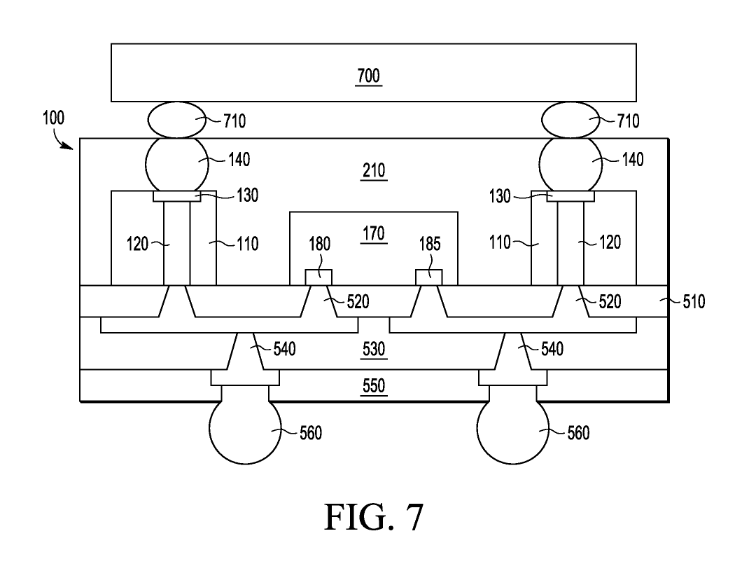

FIG. 7 also shows a cross section of device structure 100 coupled to another device structure (700) after buildup, ball placement and singulation, using the top-conductive surfaces. In this case, device 700 just shows conductive balls 710 contacting the conductive surfaces of grinded ball conductors 140. Again, conductive balls 710 are in a configuration that allows for electrical contact between device 700 and device 100 through the conductive surfaces. Embodiments of the present invention are not limited to coupling a package to the conductive surfaces of the grinded ball conductors. For example, discrete components, heat sinks, or shields can be solder coupled to the top-conductive surfaces.

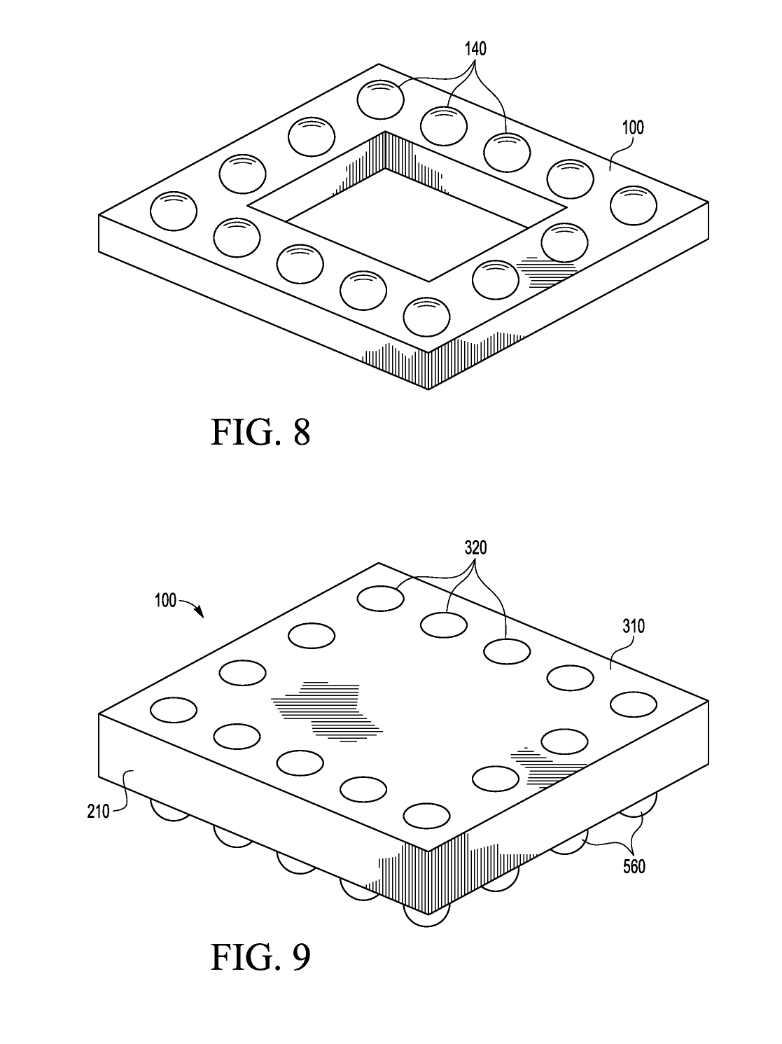

FIG. 8 is a simplified block diagram illustrating a perspective view of an example of a substrate 110 with coupled ball conductors 140. Substrate 110 is shown in a square configuration with a space in the middle for a die to be placed. It should be understood that embodiments of the present invention are not limited to a particular shape or configuration of the substrate. As discussed above, depending on the nature of the application and the package layout, alternative shapes and configurations such as strips and squares may be desirable. Embodiments of the substrate, however, will have conductors that allow for signal communication from a top side surface of the ultimate packaged device, to the bottom side surface of the packaged device. Further, ball conductors 140 are affixed to the substrate in a matter such that during a grind process of the encapsulant and a portion of the ball conductors, the ball conductors do not become detached from the substrate.

FIG. 9 is a simplified block diagram illustrating a perspective view of a packaged device 100 incorporating an embodiment of the present invention. Encapsulant 210 forms the body of packaged device 100. Top side surface 310 has been ground down to expose a portion of the ball conductors (conductive surfaces 320). In addition, ball conductors 560 are shown from the bottom side interconnect.

Embodiments of the present invention are not limited to the particular type of process illustrated in the figures. As shown, embodiments of the present invention are used in a fan-out wafer level package, (e.g. redistributed chip packaging process (RCP)), but embodiments of the present invention are not limited to fan-out wafer level package. It should be realized, however, that steps discussed above may require modification for different types of processes.

It should further be noted that embodiments of the present invention do not depend on the exact nature of the embedded component (e.g., 170 and 610). The component can be, for example, integrated circuits, individual devices, filters, magnetostrictive devices, electro-optical devices, electro-acoustic devices, integrated passive devices such as resistors, capacitors and inductors, or other types of elements and combinations thereof, and can be formed of any materials able to withstand the encapsulation process. Non-limiting examples of materials are various organic and inorganic semiconductors, type IV, III-V and II-VI materials, glasses, ceramics, metals, semi-metals, inter-metallics and the like.

Embodiments of the present invention avoid a need for processing steps related to forming an interconnect on the “back side” or top side (as illustrated) of packaged devices. In addition, incorporation of ball conductors and signal conduits that provide a signal path from one major surface of the packaged device to the other save the need for post-encapsulation via drilling and filling steps. Incorporation of the ball conductors and substrate occurs at the same stage in processing as other pick and place operations, or before pick and place. Buildup on the top side (as illustrated) is not needed as the ground surface provides a connection configuration that matches the top package for assembly. Further, the process provides consistent quality signal paths through the depth of the package that do not depend upon a quality of a fill operation.

By now it should be appreciated that a method for packaging an electronic device assembly has been provided that includes: providing an interconnect assembly including a substrate, a plurality of signal conduits embedded in the substrate and extending to a first major surface of the substrate, a substrate interconnect formed on the substrate and electrically coupling two or more of the plurality of signal conduits, and one or more conductive balls electrically coupled to the substrate interconnect at a second major surface of the interconnect assembly; placing the interconnect assembly in a first area for the electronic device assembly; placing a first electronic device in a second area for the electronic device assembly; forming an encapsulant over and around sides of the first electronic device and over and around sides of the interconnect assembly; and, exposing a portion of the one or more conductive balls where the exposing removes a portion of the encapsulant and the exposed portion of the one or more conductive balls provide electrical contacts to the interconnect assembly on a first major surface of the electronic device assembly.

One aspect of the above embodiment further includes exposing an end of the one or more signal conduits at a second major surface of the electronic device assembly, and forming a package interconnect on the second major surface of the electronic device assembly. The exposing is performed subsequent to forming the encapsulant. The package interconnect is electrically coupled to the exposed ends of the one or more signal conduits and electrical contacts of the first electronic device. In a further aspect, the package interconnect is electrically coupled to one or more of the conductive balls via one or more of the signal conduits and the substrate interconnect.

Another aspect of the above embodiment further includes providing an adhesive layer disposed on a carrier. Placing the interconnect assembly includes placing the interconnect assembly on the adhesive layer with the first major surface of the interconnect assembly in contact with the adhesive layer, and placing the first electronic device includes placing the first electronic device active side down on the adhesive layer. In a further aspect, exposing the end of the one or more signal conduits includes removing the adhesive layer from the encapsulated electronic device assembly.

In another aspect of the above embodiment, exposing the portion of the one or more conductive balls includes grinding the encapsulant from the electronic device assembly to a predetermined depth. In a further aspect the predetermined depth includes a depth resulting in a desired diameter of the exposed portion of a conductive ball of the one or more conductive balls.

In another aspect of the above embodiment, a conductive ball is a solder ball. Another aspect of the above embodiment further includes forming a package-on-package assembly. Forming the package-on-package assembly includes placing a second electronic device assembly in contact with the first major surface of the electronic device assembly, and forming an electrical contact between one or more contacts of the second electronic device assembly with one or more corresponding exposed portions of the one or more conductive balls.

In another embodiment a packaged device assembly has been provided that includes an electronic device, and interconnect assembly, encapsulant over and around the electronic device and over and around the interconnect assembly which forms an encapsulated region of the packaged device assembly, and a first interconnect structure formed on the bottom surface of the packaged device assembly. The interconnect assembly includes a substrate, a plurality of signal conduits embedded in the substrate and extending to a first major surface of the substrate, a substrate interconnect formed on the substrate and electrically coupling two or more of the plurality of signal conduits, and one or more conductive balls electrically coupled to the substrate interconnect and a second major surface of the interconnect assembly. A portion of the encapsulant is removed to expose a portion of the one or more conductive balls on a top surface of the packaged device assembly. The exposed portions of the conductive balls are electrically coupled to the first interconnect structure by one or more of the substrate interconnect and a signal conduit of the one or more signal conduits.

One aspect of the above embodiment provides for a conductive ball to be a solder ball. In another aspect, the exposed portion of the one or more conductive balls is an area sufficient to provide a coupling point for a second package device assembly attached to the top of the package device assembly. In still another aspect, the packaged device assembly further includes a second package device assembly including one or more coupling points on the major surface of the second device assembly. The one or more coupling points are coupled to the exposed portion of the one or more conductive balls on the top surface of the package device assembly and the coupled package device assembly and the second package device assembly form a package-on-package assembly.

Because the apparatus implementing the present invention is, for the most part, composed of electronic components and circuits known to those skilled in the art, circuit details are not explained in any greater extent than that considered necessary as illustrated above, for the understanding and appreciation of the underlying concepts of the present invention and in order not to obfuscate or distract from the teachings of the present invention.

The terms “front,” “back,” “top,” “bottom,” “over,” “under” and the like in the description and in the claims, if any, are used for descriptive purposes and not necessarily for describing permanent relative positions. It is understood that the terms so used are interchangeable under appropriate circumstances such that the embodiments of the invention described herein are, for example, capable of operation in other orientations than those illustrated or otherwise described herein.

Although the invention is described herein with reference to specific embodiments, various modifications and changes can be made without departing from the scope of the present invention as set forth in the claims below. Accordingly, the specification and figures are to be regarded in an illustrative rather than a restrictive sense, and all such modifications are intended to be included within the scope of the present invention. Any benefits, advantages, or solutions to problems that are described herein with regard to specific embodiments are not intended to be construed as a critical, required, or essential feature or element of any or all the claims.

Furthermore, the terms “a” or “an,” as used herein, are defined as one or more than one. Also, the use of introductory phrases such as “at least one” and “one or more” in the claims should not be construed to imply that the introduction of another claim element by the indefinite articles “a” or “an” limits any particular claim containing such introduced claim element to inventions containing only one such element, even when the same claim includes the introductory phrases “one or more” or “at least one” and indefinite articles such as “a” or “an.” The same holds true for the use of definite articles.

Unless stated otherwise, terms such as “first” and “second” are used to arbitrarily distinguish between the elements such terms describe. Thus, these terms are not necessarily intended to indicate temporal or other prioritization of such elements.

1. A method for packaging an electronic device assembly, the method comprising:
providing an interconnect assembly comprising
a substrate,
a plurality of signal conduits embedded in the substrate and extending to a first major surface of the substrate,
a substrate interconnect formed on the substrate and electrically coupling two or more of the plurality of signal conduits, and
one or more conductive balls electrically coupled to the substrate interconnect at a second major surface of the interconnect assembly;
placing the interconnect assembly in a first area for the electronic device assembly;
placing a first electronic device in a second area for the electronic device assembly;
forming an encapsulant over and around sides of the first electronic device and over and around sides of the interconnect assembly;
exposing a portion of the one or more conductive balls, wherein
performing said exposing further removes a portion of the encapsulant, and
the exposed portion of the one or more conductive balls provides electrical contacts to the interconnect assembly on a first major surface of the electronic device assembly.

2. The method of claim 1 further comprising:
exposing an end of the one or more signal conduits at a second major surface of the electronic device assembly, wherein said exposing the end is performed subsequent to said forming the encapsulant;
forming a package interconnect on the second major surface of the electronic device assembly, wherein the package interconnect is electrically coupled to the exposed ends of the one or more signal conduits and electrical contacts of the first electronic device.

3. The method of claim 1 further comprising:
providing an adhesive layer disposed on a carrier, wherein
said placing the interconnect assembly comprises placing the interconnect assembly on the adhesive layer with the first major surface of the interconnect assembly in contact with the adhesive layer, and
said placing the first electronic device comprises placing the first electronic device active side down on the adhesive layer.

4. The method of claim 3 wherein said exposing the end of the one or more signal conduits comprises removing the adhesive layer from the encapsulated electronic device assembly.

5. The method of claim 2 wherein the package interconnect is electrically coupled to one or more of the one or more conductive balls via one or more of the signal conduits and the substrate interconnect.

6. The method of claim 1 wherein said exposing the portion of the one or more conductive balls comprises:
grinding the encapsulant from the electronic device assembly to a predetermined depth.

7. The method of claim 6 wherein the predetermined depth comprises a depth resulting in a desired diameter of the exposed portion of a conductive ball of the one or more conductive balls.

8. The method of claim 1 wherein a conductive ball of the one or more conductive balls is a solder ball.

9. The method of claim 1 further comprising:
forming a package-on-package assembly, wherein said forming the package on package assembly comprises
placing a second electronic device assembly in contact with the first major surface of the electronic device assembly, and
forming an electrical contact between one or more contacts of the second electronic device assembly with one or more corresponding exposed portions of the one or more conductive balls.

10. A packaged device assembly comprising:
an electronic device;
an interconnect assembly comprising
a substrate,
a plurality of signal conduits embedded in the substrate and extending to a first major surface of the substrate,
a substrate interconnect formed on the substrate and electrically coupling two or more of the plurality of signal conduits, and
one or more conductive balls electrically coupled to the substrate interconnect at a second major surface of the interconnect assembly;
encapsulant over and around the electronic device and over and around the interconnect assembly and forming an encapsulated region of the packaged device assembly, wherein
a portion of the encapsulant is removed to expose a portion of the one or more conductive balls on a top surface of the packaged device assembly; and
a first interconnect structure formed on the bottom surface of the packaged device assembly, wherein
the exposed portions of the conductive balls are electrically coupled to the first interconnect structure by one or more of the substrate interconnect and a signal conduit of the one or more signal conduits.

11. The packaged device assembly of claim 10 wherein a conductive ball of the one or more conductive balls comprises a solder ball.

12. The packaged device assembly of claim 10 wherein the exposed portion of the one or more conductive balls on the top surface of the packaged device assembly comprises an area sufficient to provide a coupling point for a second packaged device assembly attached to the top of the packaged device assembly.

13. The packaged device assembly of claim 10 further comprising:
a second packaged device assembly comprising one or more coupling points on a major surface of the second packaged device assembly, wherein
the one or more coupling points are coupled to the exposed portion of the one or more conductive balls on the top surface of the packaged device assembly, and
the coupled packaged device assembly and the second packaged device assembly form a package-on-package assembly.

14. The packaged device assembly of claim 10 further comprising:
an electrical component comprising electrical contacts coupled to the exposed portion of one or more of the one or more conductive balls on the top surface of the packaged device assembly.

15. The packaged device assembly of claim 10, wherein
the interconnect assembly forms a region in which the electronic device is placed.

16. The packaged device assembly of claim 10, wherein
the interconnect assembly comprises a plurality of substrates.

17. A packaged device assembly comprising:
encapsulant forming an encapsulated region of the packaged device assembly;
one or more electrical contacts on a first major surface of the packaged device assembly, wherein the electrical contacts comprise exposed portions of conductive balls encapsulated in the encapsulant; and
a package interconnect structure formed on a second major surface of the packaged device assembly, wherein
a conductive ball of the conductive balls is electrically coupled to the package interconnect structure by an internal interconnect, and
the internal interconnect is encapsulated in the encapsulant.

18. The packaged device assembly of claim 17 wherein the internal interconnect comprises:
a substrate;
a plurality of signal conduits embedded in the substrate and extending to a first major surface of the substrate; and
a substrate interconnect formed on the substrate and electrically coupling two or more of the plurality of signal conduits, wherein
the substrate interconnect is coupled to the conductive ball of the conductive balls.

19. The packaged device assembly of claim 17 further comprising:
an electronic device encapsulated in the encapsulant, wherein the electronic device is electrically coupled to one or more of the package interconnect and the internal interconnect.

20. A package-on-package assembly comprising the packaged device assembly of claim 17 and an electronic device electrically coupled to the one or more electrical contacts on the first major surface of the packaged device assembly.
